(19) United States
(12) Patent Application Publication
(10) Pub. No.: US 2024/0076440 A1
(43) Pub. Date: Mar. 7, 2024

(54) PROCESS OF FORMING A CONJUGATED POLYMER

(71) Applicant: Sumitomo Chemical Co., ltd., Tokyo (JP)

(72) Inventors: Philip Stackhouse, Godmanchester (GB); Martin Humphries, Godmanchester (GB)

(21) Appl. No.: 17/766,507

(22) PCT Filed: Oct. 2, 2020
(86) PCT No.: PCT/GB2020/052424

§ 371 Date: Apr. 4, 2022

(30) Foreign Application Priority Data
Oct. 4, 2019 (GB) 1914389.0

(51) Int. Cl. C08G 61/02

(52) U.S. Cl. CPC C08G 61/02; C08G 2261/124; C08G 2261/1412; C08G 2261/143; C08G 2261/18; C08G 2261/228; C08G 2261/3142; C08G 2261/41

(57) ABSTRACT

A process of forming a conjugated polymer comprising polymerising a first monomer and a second monomer in the presence of a palladium catalyst and a base, in a solvent system comprising a first solvent, a second solvent and water; wherein: the first and second monomers are is dissolved in the solvent system; and the solvent system is a single phase. The first monomer may be substituted with a polar group, e.g. an ionic group.

### BACKGROUND

Embodiments of the present disclosure relate to a method of forming conjugated polymers by palladium-catalysed polymerisation.

One method of forming conjugated polymers is Suzuki polymerisation, for example as described in WO 00/53656 or U.S. Pat. No. 5,777,070 which disclose formation of C—C bonds between monomers having aromatic or heteroaromatic groups.

WO 2012/133229 discloses formation of polymers containing ester groups which are converted following polymerisation to carboxylate groups.

### SUMMARY

A summary of aspects of certain embodiments disclosed herein is set forth below. It should be understood that these aspects are presented merely to provide the reader with a brief summary of these certain embodiments of the present disclosure and that these aspects are not intended to limit the scope of this disclosure. Indeed, this disclosure may encompass a variety of aspects and/or a combination of aspects that may not be set forth.

According to some embodiments of the present disclosure, there is provided a process of forming a conjugated polymer comprising polymerising a first monomer and a second monomer in the presence of a palladium catalyst and a base, in a solvent system comprising a first solvent, a second solvent and, preferably, water.

The first and second monomers are dissolved in the solvent system.

The solvent system is a single phase.

The first monomer is a compound of Formula 1:

X¹-Ar¹-X¹ Formula 1

wherein Ar¹ comprises at least one aromatic or heteroaromatic group and is substituted with at least one polar substituent. The polar substituent may be ionic or non-ionic.

The second monomer is a compound of Formula 2:

X²-Ar²-X² Formula 2:

wherein Ar² comprises at least one aromatic or heteroaromatic group.

Each X¹ and X² is individually selected from a halogen, —OSO₂R^{a}, boronic acid, and a boronic ester, wherein R^{a} is an optionally substituted aryl or alkyl group; and at least one X¹ or X² is a halogen or —OSO₂R^{a}, the remaining X¹ and X² groups being a boronic acid, or a boronic ester.

In some embodiments, the first monomer is substituted with at least one ionic group and, optionally, one or more non-ionic substituents.

In some embodiments, the first monomer is not substituted with ionic groups. According to these embodiments, the first monomer is substituted with one or more non-ionic substituents comprising or consisting of polar, non-ionic substituents. According to some embodiments of the present disclosure, the second solvent is a non-polar solvent.

According to some embodiments of the present disclosure, the second solvent is selected from benzene having one or more alkyl substituents or a mixture thereof.

According to some embodiments of the present disclosure, the second solvent is immiscible with water.

According to some embodiments of the present disclosure, the first solvent is a polar solvent.

According to some embodiments of the present disclosure, the first solvent is a protic solvent.

According to some embodiments of the present disclosure, the first solvent is selected from C₁₋₁₀ alcohols or diols, tetrahydrofuran, acetic acid, acetone, dimethyl sulfoxide, N,N-dimethylformamide, acetonitrile or a mixture thereof.

According to some embodiments of the present disclosure, the first solvent is selected from methanol, ethanol, propanol and butanol.

According to some embodiments of the present disclosure, the first solvent is miscible with water.

According to some embodiments of the present disclosure, the first solvent is miscible with the second solvent.

According to some embodiments of the present disclosure, at least one of Ar¹ and Ar² is an arylene group.

According to some embodiments of the present disclosure, the arylene group is selected from:

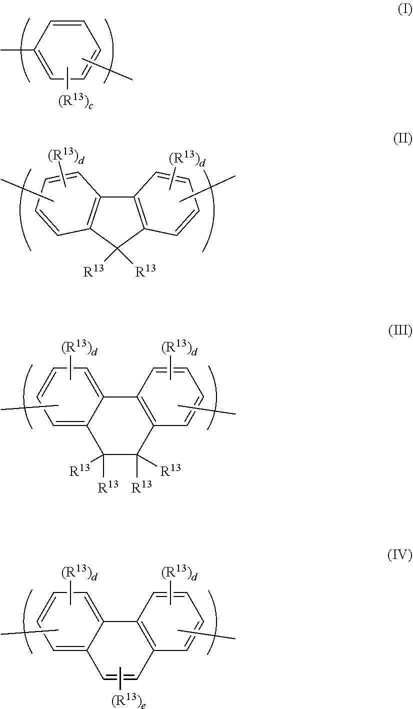

wherein each R¹³ is independently a substituent; c is 0, 1, 2, 3 or 4, each d is independently 0, 1, 2 or 3; and e is 0, 1 or 2, preferably 2.

According to some embodiments of the present disclosure, Ar¹ is an arylene group selected from formulae (I)-(IV), optionally (II)-(IV).

According to some embodiments of the present disclosure, Ar² is an arylene group selected from formulae (I)-(IV), optionally (II)-(IV).

According to some embodiments of the present disclosure, Ar² comprises a heteroarylene or a (hetero)arylamine group.

According to some embodiments of the present disclosure, each Ar² is unsubstituted or substituted only with one or more non-ionic substituents.

According to some embodiments of the present disclosure, the first monomer is substituted with one or more ionic substituents of formula -(Sp)m-(R^{x})n wherein Sp is a spacer group; m is 0 or 1; R^{x} in each occurrence is an ionic group; n is 1 if m is 0; and n is at least 1, optionally 1, 2, 3 or 4, if m is 1.

According to some embodiments of the present disclosure, each ionic group is individually selected from the following groups:

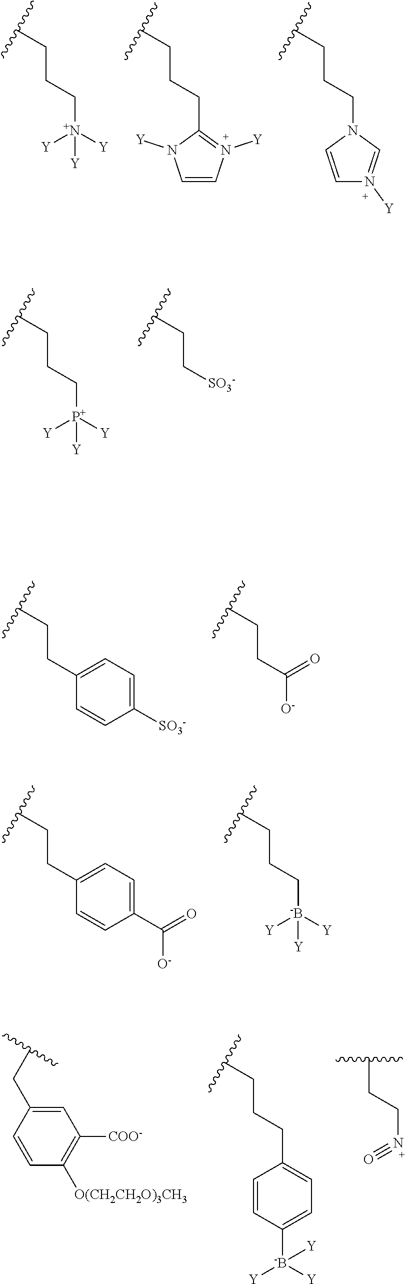

wherein each Y is individually selected from H, C₁-C₂₀ hydrocarbyl groups and C₁₋₃₀ alkyl in which one or more non-adjacent C atoms other than C atoms at the ends of the alkyl chain are replaced with O.

In some embodiments, there is provided a process of forming a conjugated polymer comprising polymerising a first monomer and a second monomer in the presence of a palladium catalyst and a base, in a solvent system comprising a first solvent and a second solvent; wherein:
the first and second monomers are dissolved in the solvent system;
the solvent system is a single phase;
the first monomer is a compound of Formula 1:

X¹-Ar¹-X¹ Formula 1

wherein Ar¹ comprises at east one aromatic or heteroaromatic group;
the second monomer is a compound of Formula 2:

X²-Ar²-X² Formula 2:

wherein Ar² comprises at least one aromatic or heteroaromatic group;
each X¹ and X² is individually selected from a halogen, —OSO₂R^{a}, boronic acid, and a boronic ester; wherein R^{a} is an optionally substituted aryl or alkyl group; and at least one X¹ or X² is a halogen or —OSO₂R^{a}, the remaining X¹ and X² groups being a boronic acid, or a boronic ester;
the first monomer has a greater solubility in water at 25° C. than the second monomer; and
the second monomer has a greater solubility in toluene at 25° C. than the first monomer.

It will be understood that the solubility of substituents of the first monomer and the second monomer may be adjusted by selection from any substituents described herein.

### DESCRIPTION OF DRAWINGS

FIG. 1 shows the FT-IR spectra for a first polymer according to some embodiments of the present disclosure and the monomers used to form that polymer;

FIG. 2 shows the FT-IR spectra for a second polymer according to some embodiments of the present disclosure and the monomers used to form that polymer; and

FIG. 3 shows the absorption spectra for the second polymer and a monomer used to form that polymer.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that a conjugated polymer having repeat units with polar, e.g. ionic, substituents may be formed by polymerisation of monomers in which at least one monomer is substituted with at least one polar substituent by use of a single phase solvent system containing a first solvent, a second solvent and, optionally, water and in which the first and second monomers dissolve. Consequently, an additional post-polymerisation functionalisation step of a polymer to convert a non-ionic substituent to an ionic substituent may be avoided, and impurities arising from unconverted polymer in any post-polymerisation functionalisation step may be avoided. The present inventors also have found that the present polymerisation allows for the formation of polymers with ionic groups that cannot be readily formed using post-polymerisation functionalisation.

As illustrated in Scheme 1, a monomer for forming repeat units Ar¹ having leaving groups X¹ undergoes polymerisation with a monomer for forming repeat units Ar² (which may be the same as or different from Ar¹) having leaving groups X² to form a carbon-carbon bond between sp2 hybridised carbon atoms of Ar¹ and Ar²:

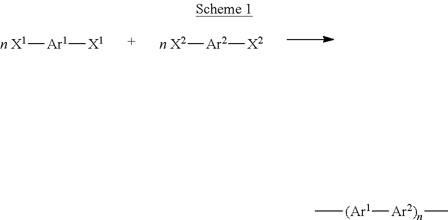

It will be understood by the skilled person that when both X¹s are the same, a monomer X¹-Ar¹-X¹ will not polymerise to form a direct carbon-carbon bond with another monomer X¹-Ar¹-X¹. When both X²s are the same, a monomer X²-Ar²-X² will not polymerise to form a direct carbon-carbon bond with another monomer X²-Ar²-X².

This selectivity means that the ordering of repeat units in the polymer backbone can be controlled such that all or substantially all Ar¹ repeat units formed by polymerisation of X¹-Ar¹-X¹ are adjacent, on both sides, to Ar² repeat units.

In the example of Scheme 1 above, an AB copolymer is formed by copolymerisation of two monomers in a 1:1 ratio, however, it will be appreciated that more than two different monomers may be used in the polymerisation, and any ratio of monomers may be used.

According to some embodiments of the present disclosure there is provided a process of forming a conjugated polymer comprising polymerising at least one first monomer and at least one second monomer in the presence of a palladium catalyst and a base, in a solvent system comprising a first solvent, a second solvent and, optionally, water, wherein the first solvent dissolves the first monomer and the second solvent dissolves the second monomer.

The first monomer is a compound of Formula 1:

X¹-Ar¹-X¹ Formula 1

wherein Ar¹ comprises at least one aromatic or heteroaromatic group and is substituted with at least one polar substituent, e.g. at least one ionic substituent; each X¹ is bound directly to an sp² hybridised carbon atom of Ar¹ and is individually selected from the group consisting of a halogen, —OSO₂R^{a}, boronic acid, and a boronic ester, wherein R^{a} is an optionally substituted aryl or alkyl group.

The second monomer is a compound of Formula 2:

X²-Ar²-X² Formula 2:

wherein Ar² comprises at least one aromatic or heteroaromatic group; each X² is bound directly to an sp² hybridised carbon atom of Ar² and is individually selected from a halogen, —OSO₂R^{a}, boronic acid, and a boronic ester, wherein R^{a} is an optionally substituted aryl or alkyl group.

Preferably, each X¹ is bound directly to a carbon atom of an aromatic or heteroaromatic ring.

Preferably, each X² is bound directly to a carbon atom of an aromatic or heteroaromatic ring.

Any two of the X¹ and X² groups of Monomers 1 and 2 are selected from a halogen or —OSO₂R^{a}; and the other two of the X¹ and X² groups are selected from boronic acid, or a boronic ester.

The first and second monomers include monomers in which at least one X¹ or X² is a halogen or —OSO₂R^{a}, the remaining X¹ and X² groups being a boronic acid, or a boronic ester.

In some embodiments, each X¹ is boronic acid, or a boronic ester and each X² is a halogen or —OSO₂R^{a}.

In some embodiments, each X¹ is a halogen or —OSO₂R^{a} and each X² is a boronic acid, or a boronic ester.

In some embodiments, one X¹ is a boronic acid or a boronic ester and the other X¹ is a halogen or —OSO₂R^{a} and/or one X² is a boronic acid or a boronic ester and the other X² is a halogen or —OSO₂R^{a}.

Optionally, at least 40 mol %, optionally at least 45 mol %, preferably 50 mol %, of the X¹ and X² groups are a boronic acid or a boronic ester and at least 40 mol %, optionally at least 45 mol %, preferably 50 mol %, of the X¹ and X² groups are a halogen or —OSO₂R^{a}.

Conjugated Polymer

The conjugated polymer may be a homopolymer or may be a copolymer comprising two or more different repeat units.

By “conjugated polymer” is meant a polymer comprising repeat units in the polymer backbone that are directly conjugated to adjacent repeat units. The conjugation may extend across the whole of the polymer backbone or partially across the polymer backbone, i.e. each repeat unit may have one or more structural sub-units that are conjugated or that break any conjugation path across the repeat unit.

Conjugated polymers include, without limitation, polymers comprising one or more of arylene, heteroarylene and vinylene groups conjugated to one another along the polymer backbone.

The polymer may have a linear, branched or crosslinked backbone.

The polymer may have a solubility of at least 0.01 mg/ml in an alcoholic solvent, optionally in the range of 0.01-10 mg/ml. Optionally, solubility is at least 0.1 or 1 mg/ml. The solubility is measured at 25° C. Preferably, the alcoholic solvent is a C₁₋₁₀ alcohol, more preferably methanol. Solubility of the polymer may be adjusted by selection of substituents of the polymer. The polymer may have a solubility of at least 0.01 mg/ml in water at 25° C., optionally a solubility in the range of 0.01-10 mg/ml

Ionic Substituents

Ar¹ is substituted with at least one polar substituent, optionally at least one ionic substituent.

Ar² may or may not be substituted with one or more polar, e.g. ionic, substituents.

Exemplary ionic substituents have formula -(Sp)m-(R^{x})n wherein Sp is a spacer group; m is 0 or 1; R^{x} independently in each occurrence is an ionic group; n is 1 if m is 0; and n is at least 1, optionally 1, 2, 3 or 4, if m is 1.

Preferably, Sp is selected from:
C₁₋₂₀ alkylene or phenylene-C₁₋₂₀ alkylene wherein one or more non-adjacent C atoms may be replaced with O; S, N or C═O;
a C₆₋₂₀ arylene or 5-20 membered heteroarylene, more preferably phenylene, which, in addition to the one or more substituents R^{x} may be unsubstituted or substituted with one or more substituents, optionally one or more C₁₋₂₀ alkyl groups wherein one or more non-adjacent, non-terminal C atoms may be replaced with O, S, CO, COO, NR¹ or SiR¹₂ wherein R¹ is a C₁₋₁₂ hydrocarbyl group.

R^{x} may be an anionic or cationic group. Exemplary anionic groups are —COO⁻, a sulfonate group; hydroxide; sulfate; phosphate; phosphinate; or phosphonate. An exemplary cationic group is —N(R⁵)₃⁺ wherein R⁵ in each occurrence is H or C₁₋₁₂ hydrocarbyl. Preferably, each R⁵ is a C₁₋₁₂ hydrocarbyl.

Exemplary ionic substituents are:

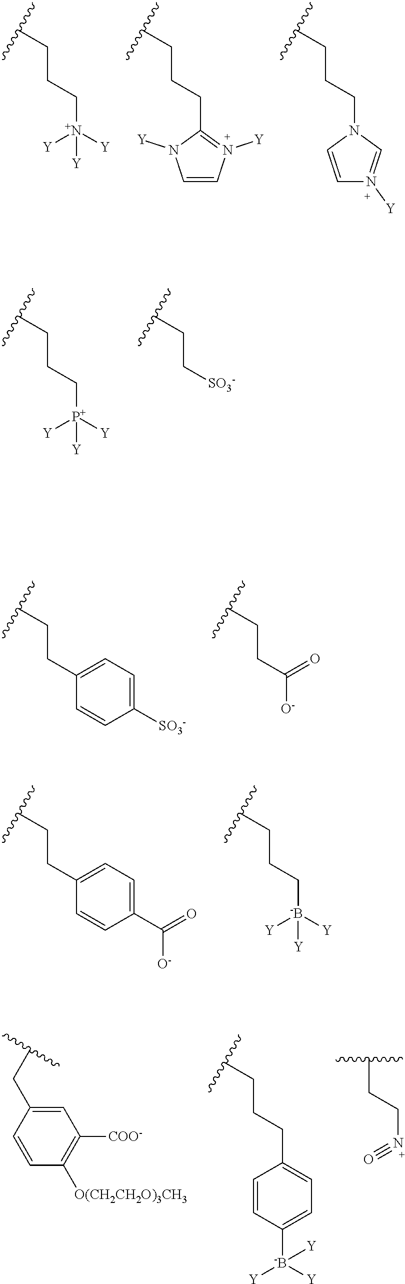

wherein each Y is individually selected from H, C₁-C₂₀ hydrocarbyl groups and C₁₋₃₀ alkyl in which one or more non-adjacent C atoms other than C atoms at the ends of the alkyl chain are replaced with O. For example, each Y may be selected from C₁-C₂₀ alkyl, C₂-C₂₀ alkenyl, C₆-C₂₀ aryl group, C₃-C₂₀ aliphatic cyclic groups and groups of formula —(CH₂CH₂O)ₙAk wherein n is at least 1, optionally 1-10, and Ak is C₁₋₅ alkyl. For example, each Y may be selected from methyl, ethyl, propyl, butyl, phenyl or tolyl groups.

Where an ionic substituent is present, the polymer further comprises a charge-balancing counterion to balance the charge of the ionic substituents.

Cationic counterions are optionally selected from a metal cation, optionally Li⁺, Na⁺, K⁺, Cs⁺, preferably Cs⁺, or an organic cation, optionally ammonium, such as tetraalkylammonium, ethylmethyl imidazolium or pyridinium.

Anionic counterions are optionally selected from a halide; a sulfonate group, optionally mesylate or tosylate; hydroxide; carboxylate; sulfate; phosphate; phosphinate; phosphonate; or borate.

Non-Ionic Substituents

Ar² is preferably substituted with at least one non-ionic substituent. In some embodiments, Ar² is unsubstituted or substituted with one or more non-ionic substituents only.

In some embodiments, Ar¹ is substituted with one or more ionic substituents only. In some embodiments, Ar¹ is substituted with at least one non-ionic substituent.

Exemplary non-ionic substituents are:
C₁₋₂₀ alkyl wherein one or more non-adjacent, non-terminal C atoms may be replaced with O, S, CO, COO, NR¹ or SiR¹₂ wherein R¹ is a C₁₋₁₂ hydrocarbyl group; and
C₆₋₂₀ aryl, e.g. phenyl, which is unsubstituted or substituted with one or more substituents, optionally one or more substituents selected from F; CN; NO₂; and C₁₋₁₂ alkyl wherein or more non-adjacent, non-terminal C atoms may be replaced with O, S, CO, COO, NR¹ or SiR¹₂.

A “non-terminal C atom” of an alkyl group as used herein means a C atom other than the C atom of the methyl group at the end of an n-alkyl group or the C atom of the methyl groups at the ends of a branched alkyl chain.

Preferably, any non-ionic substituents of Ar² are non-polar, e.g. C₁₋₂₀ hydrocarbyl groups including, without limitation, C₁₋₂₀ alkyl, unsubstituted phenyl and phenyl substituted with one or more C₁₋₆ alkyl groups

Preferably, any non-ionic substituents of Ar¹ are non-polar. An exemplary non-ionic polar group has formula —O(R¹⁴O)_{q}—R¹⁵ wherein R¹⁴ in each occurrence is a C₁₋₁₀ alkylene group, optionally a C₁₋₅ alkylene group, preferably —C₂H₄—, wherein one or more non-adjacent, non-terminal C atoms of the alkylene group may be replaced with O, R¹⁵ is H or C₁₋₅ alkyl, and q is at least 1, optionally 1-10. Preferably, q is at least 2. More preferably, q is 2 to 5. The value of q may be the same in all the polar groups of formula —O(R¹⁴O)_{q}—R¹⁵. The value of q may differ between polar groups of the same polymer.

Repeat Units

The repeat unit Ar¹ formed by polymerisation of Monomer 1 contains at least one arylene or heteroarylene group and is substituted with at least one polar substituent, e.g. at least one ionic substituent. The one or more substituents of Ar¹ may be ionic only, non-ionic only or a combination thereof.

The repeat unit Ar² formed by polymerisation of Monomer 2 contains at least one arylene or heteroarylene group. Ar² may be unsubstituted or substituted with one or more substituents which may independently be ionic or non-ionic.

Preferably, the or each Monomer 1 has greater solubility than the or each Monomer 2 in water at 25° C.

Preferably, the or each Monomer 2 has greater solubility than the or each Monomer 1 in toluene in water at 25° C.

It will be understood that the solubilities of Monomers 1 and 2 may be adjusted by selection of their substituents.

Exemplary repeat units Ar¹ and Ar² include arylene repeat units; heteroarylene repeat units; and (hetero)arylamine repeat units.

Arylene repeat units may be selected from phenylene, fluorene, benzofluorene, phenanthrene, dihydrophenanthrene, naphthalene and anthracene, more preferably fluorene or phenylene, most preferably fluorene.

The, or each, arylene repeat unit may be unsubstituted or substituted with one or more substituents selected from ionic and non-ionic substituents. Preferably, at least one arylene repeat unit is substituted with at least one ionic group.

The repeat units of a light-emitting polymer may consist of one or more arylene repeat units as described herein.

Arylene repeat units may be selected from repeat units of formulae (I)-(IV):

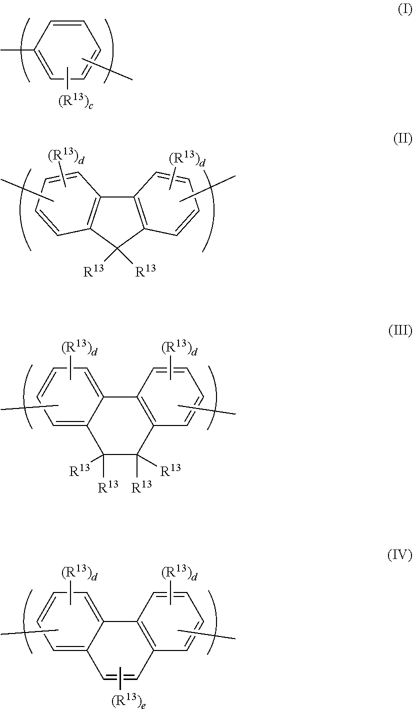

wherein each R¹³ is a substituent, optionally an ionic or non-ionic substituent as described above; c is 0, 1, 2, 3 or 4, preferably 1 or 2; each d is independently 0, 1, 2 or 3, preferably 0 or 1; and e is 0, 1 or 2, preferably 2.

In the case where Ar¹ is a repeat unit of formula (I), (II), (III) or (IV), at least one R¹³ is a polar substituent, preferably an ionic substituent.

In the case where Ar² is an arylene repeat unit, optionally a repeat unit of formula (I), (II), (III) or (IV), it is optionally unsubstituted or substituted with one or more ionic or non-ionic substituents. In some preferred embodiments, an arylene repeat unit Ar² is substituted with non-ionic substituent only, optionally one or more C₁₋₂₀ hydrocarbyl groups. Hydrocarbyl groups as described herein include, without limitation, C₁₋₂₀ alkyl, unsubstituted phenyl and phenyl substituted with one or more C₁₋₆ alkyl groups.

In some embodiments of the present disclosure, the conjugated polymer is a homopolymer formed by polymerizing monomers in which Ar¹ and Ar² are the same.

In some embodiments, the conjugated polymer is a copolymer comprising two or more different repeat units. The copolymer may be formed by polymerizing monomers in which: at least one first monomer has an Ar¹ group which is different from Ar² of at least one second monomer; there are at least two different first monomers having different Ar¹ groups; and/or there are at least two different second monomers having different Ar² groups.

In some embodiments, the copolymer contains two different arylene repeat units. In some embodiments, the copolymer contains at least one arylene repeat unit and at least one repeat unit selected from heteroarylene repeat units and (hetero)arylamine repeat units.

Arylene repeat units of a copolymer preferably form 50-100 mol % of the repeat units of the polymer.

Exemplary heteroarylene repeat units include repeat units of formulae (V), (VI) and (VII):

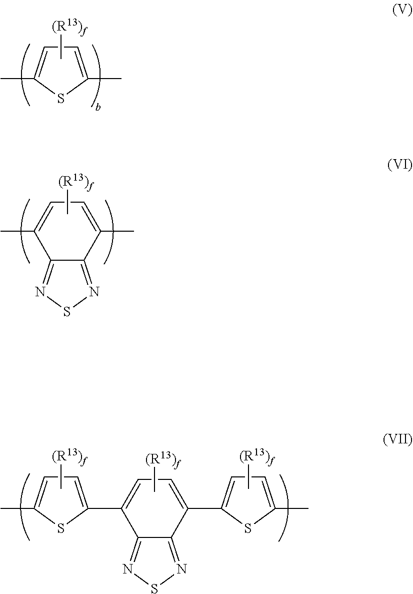

wherein R¹³ in each occurrence is as described above and f is 0, 1 or 2 if the heteroarylene repeat unit is a group Ar² or at least one R¹³ is present (at least one f is 1) and is a polar substituent, e.g. an ionic substituent, if the heteroarylene repeat unit is a group Ar¹.

(Hetero)arylamine repeat units of the conjugated polymer may have formula (VIII):

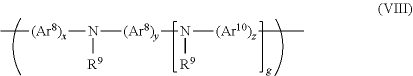

wherein Ar⁸, Ar⁹ and Ar¹⁰ in each occurrence are independently selected from substituted or unsubstituted aryl or heteroaryl, g is 0, 1 or 2, preferably 0 or 1, and x, y and z are each independently 1, 2 or 3.

R⁹, which may be the same or different in each occurrence when g is 1 or 2, is preferably selected from the group consisting of alkyl, optionally C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar¹⁰ and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ arylene, more preferably phenylene, that may be unsubstituted or substituted with one or more substituents, optionally one or more substituents selected from ionic and non-ionic substituents R¹³.

In the case where g=0, Ar⁹ is preferably C₆₋₂₀ arylene, more preferably phenylene, that ay be unsubstituted or substituted with one or more substituents.

In the case where g=1, Ar⁹ is preferably C₆₋₂₀ arylene, more preferably phenylene or a polycyclic arylene group, for example naphthalene, perylene, anthracene or fluorene, that may be unsubstituted or substituted with one or more substituents.

R⁹ is preferably Ar¹¹ or a branched or linear chain of Ar¹¹ groups. Ar¹¹ in each occurrence is preferably phenyl that may be unsubstituted or substituted with one or more substituents.

Exemplary groups R⁹ include the following, each of which may be unsubstituted or substituted with one or more substituents, and wherein * represents a point of attachment to N:

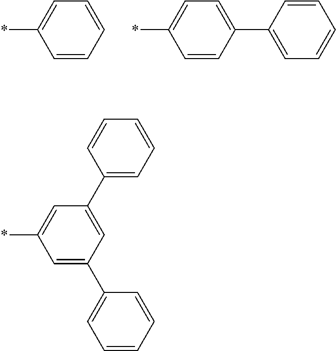

x, y and z are preferably each 1.

Ar⁸, Ar⁹, and, if present, Ar¹⁰ and Ar¹¹ are each independently unsubstituted or substituted with one or more, optionally 1, 2, 3 or 4, substituents.

Substituents may independently be a group R¹³ as described above.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (VIII) include unsubstituted or substituted units of formulae (VIII-1), (VIII-2) and (VIII-3):

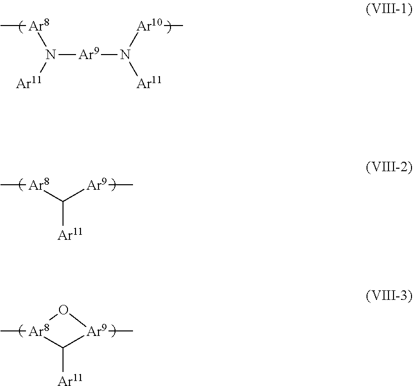

In the case where the conjugated polymer is used as a light-emitting polymer, the or each repeat unit of the polymer may be selected to produce a desired colour of emission of the polymer.

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Polymers as described herein are suitably amorphous polymers.

Leaving Groups

Each X¹ and X² is individually selected from a halogen (preferably bromine or iodine) —OSO₂R^{a}, boronic acid, and a boronic ester, wherein R^{a} is an optionally substituted aryl or alkyl group.

—OSO₂R^{a} is preferably tosylate or vitiate.

Exemplary boronic esters have formula (IX):

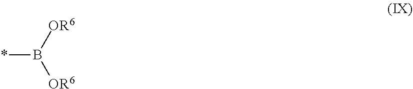

wherein R⁶ in each occurrence is independently a C₁₋₂₀ alkyl group, * represents the point of attachment of the boronic ester to an aromatic ring of the monomer, and the two groups R⁶ may be linked to form a ring. In a preferred embodiment, the two groups R⁶ are linked, e.g. to form:

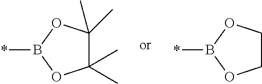

Solvent System

The first solvent, second solvent and, where present, water form a single phase. As used herein, a single phase refers to homogenous liquid phase. It does not include an emulsion.

The first solvent dissolves the first monomer.

According to some embodiments of the present disclosure the first solvent is a polar solvent. The polar solvent may or may not be a protic solvent. The second solvent may be selected from a C₁₋₁₀ alcohol or diol, e.g. methanol, ethanol, methanol, butanol, propanol, tetrahydrofuran, acetic acid, acetone, dimethyl sulfoxide, N.N-dimethylformamide, acetonitrile, dimethoxyethane, and chlorinated solvents, e.g. dichloromethane or chloroform.

According to some embodiments of the present disclosure the second solvent is a non-polar solvent. The second solvent may be selected from a substituted or unsubstituted C₆₋₁₅ alkane, a substituted or unsubstituted C₄₋₁₅ aliphatic cyclic compound or a substituted or unsubstituted C₆₋₁₅ aryl compound. The first solvent may be selected from, benzene; a substituted benzene e.g. benzene with one or more alkyl substituents such as xylene or toluene; and tetrahydrofuran.

A substituent of a substituted solvent as described herein may be selected from C₁-C₆ alkyl, C₂-C₆ alkenyl, C₂-C₆ alkenyl, C₃₋₁₄ cyclic group, C₁₋₆ alkoxy, C₁₋₆ and alkylthio.

The second solvent dissolves the second monomer.

According to some embodiments of the present disclosure, the first solvent is miscible with water.

According to some embodiments of the present disclosure, the first solvent is miscible with the second solvent.

According to some embodiments of the present disclosure, the second solvent is immiscible with water. In these embodiments, the first solvent is provided in a sufficient amount to form a single phase with the first and second solvents.

In some embodiments of the present disclosure, formation of a polymerisation mixture comprises adding the second solvent to a mixture comprising the first and second monomers, and the first solvent.

In some embodiments of the present disclosure, formation of a polymerisation mixture comprises adding the second solvent to a mixture comprising the first and second monomers, the catalyst, water and the first solvent.

Catalyst

The polymerisation takes place in the presence of a palladium complex catalyst and a base.

The catalyst may be a palladium (0) or palladium (II) catalyst.

The catalyst may comprise phosphine ligands, e.g. ligands of formula PR³₃ wherein each R³ is independently selected from C₁₋₁₂ alkyl and aryl, preferably phenyl, which may be unsubstituted or substituted with one or more substituents, optionally one or more substituents selected from C₁₋₁₂ alkyl and C₁₋₁₂ alkoxy.

If the catalyst is a Pd (II) catalyst then anions include C₁₋₁₀ alkoxy and halides, for example chloride bromide or iodide.

In some embodiments, the catalyst is provided in a preformed state in the polymerisation mixture at the start of polymerisation, in which the ligands, e.g. the phosphine ligands, are coordinated to the platium.

In some embodiments a ligand, e.g. phosphine, is provided with a platinum compound which itis not coordinated to, e.g. Pt(II)halide, at the start of the polymerisation.

The base may be an organic or inorganic base. Exemplary organic bases include tetra-alkylammonium hydroxides, carbonates and bicarbonates. Exemplary inorganic bases include metal (for example alkali or alkali earth) hydroxides, carbonates and bicarbonates.

The palladium complex catalyst may be a palladium (0) or palladium (II) compound.

Particularly preferred catalysts are tetrakis(triphenylphosphine)palladium (0) and palladium (II) acetate mixed with a phosphine,

A phosphine may be provided, either as a ligand of the palladium compound catalyst or as a separate compound added to the polymerisation mixture. Exemplary phosphines include triarylphosphines, for example triphenylphosphines wherein each phenyl may independently be unsubstituted or substituted with one or more substituents, for example one or more C₁₋₅ alkyl or C₁₋₅ alkoxy groups.

Particularly preferred are triphenylphospine and tris(ortho-methoxytriphenyl) phospine.

The polymer may be end-capped by addition of an end-capping reactant. Suitable end-capping reactants are aromatic or heteroaromatic materials substituted with only one leaving group. The end-capping reactants may include reactants substituted with a halogen for reaction with a boronic acid or boronic ester group at a polymer chain end, and reactants substituted with a boronic acid or boronic ester for reaction with a halogen at a polymer chain end. Exemplary end-capping reactants are halobenzenes, for example bromobenzene, and phenylboronic acid. End-capping reactants may be added during or at the end of the polymerisation reaction.

Applications

Polymers formed by the process described herein may be used in, without limitation, luminescent markers and organic electronic devices. A luminescent marker configured to bind to a biomolecule may contain a polymer as described herein, for example as disclosed in WO 2018/060722, the contents of which are incorporated herein by reference. Organic electronic devices include, for example, organic light-emitting devices, organic field-effect transistors, electrochromic colour-changing displays, chemical and biological sensors and organic photoresponsive devices, e.g. organic photovoltaic or photodetector devices. A polymer as described herein may be used as a conjugated polyelectrolyte.

### POLYMER EXAMPLE 1

Polymer Example 1 was formed by polymerisation of Monomers 1 and 2, as illustrated in Scheme 1:

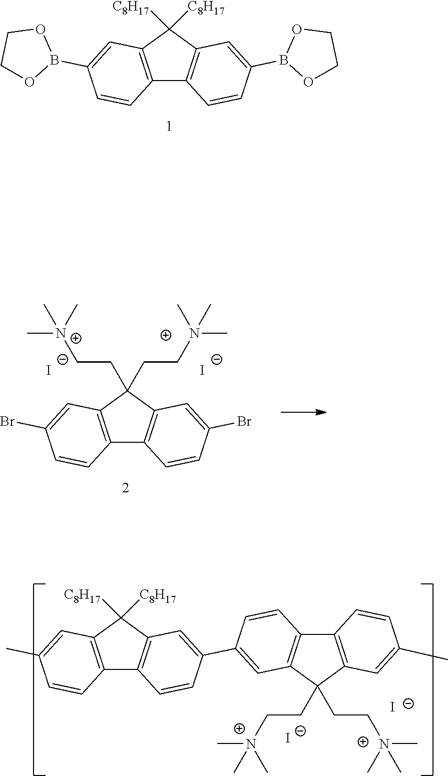

Solubilities of Monomers 1 and 2 are given in Tables 1 and 2, respectively.

TABLE 1

| Conc | | Toluene | MeOH | Water |
|---|---|---|---|---|
| 0.1 | mg/ml | Soluble | Soluble | |
| 1 | mg/ml | Soluble | Soluble | Insoluble |
| 1 | g/ml | Soluble | — | |
| 2 | g/ml | Soluble | — | |
| 50 | mg/ml | — | Soluble | |
| 75 | mg/ml | soluble | Not Soluble | |

TABLE 2

| Conc | | Toluene | MeOH | Water |
|---|---|---|---|---|
| 0.1 | mg/ml | Insoluble | | |
| 1 | mg/ml | Insoluble | | Soluble |
| 1 | g/ml | | | |
| 2 | g/ml | | | |
| 50 | mg/ml | | Soluble | Insoluble |
| 75 | mg/ml | | | |

A reaction vessel was charged with monomer 1 (1.18 g, 2.23 mmol) and monomer 2 (1.88 g, 2.25 mmol) and the vessel was purged with nitrogen overnight. Toluene (45 ml, degassed by sparging with nitrogen for 30 mins) and methanol (25 ml, degassed by sparging with nitrogen for 30 mins) was added to the reaction vessel. The mixture was stirred until a clear solution was obtained, and the resulting stirred mixture was degassed (30 min sparging with nitrogen). PdCl₂[P(o-MeOPh)₃]₂ (6 mg, 0.0068 mmol) was added to the mixture which was stirred and heated (oil bath 90° C., internal temperature 60° C.). A degassed (sparged with nitrogen for 1 h) solution of sodium carbonate (1.121 g, 10.58 mmol) in water (11.21 ml) was added dropwise to the stirred, heated reaction mixture, After ca. 2 h additional degassed toluene (20 ml) and degassed methanol (20 ml) were added to the cloudy reaction mixture, which then cleared. After a further ca., 3 h, a dark colour was observed, so PdCl₂[P(o-MeOPh)₃]₂ (6 mg, 0.0068 mmol) was added to the mixture and the reaction was continued for a further 14 h. To the stirred, heated reaction mixture, 2,6-dimethylphenyl boronic acid (0.135 g, 0.9 mmol), in a mixture of toluene (2 ml) and methanol (2 ml), and PdCl₂[P(o-MeOPh)₃]₂ (0.0060 g, 0.0068 mmol) was added. The resulting solution was stirred and heated for 14 hours, then it was cooled to room temperature. The stirred mixture was heated (oil bath, 85° C.) and sodium diethyldithiocarbamate (2.5 g, 11.1 mmol) and water (14 mL) were added and the heated mixture stirred together for 2 h. The mixture was cooled to room temperature, and the aqueous phase removed. The polymer was dried in vacuo to yield a dark solid, which was dissolved in a mixture of toluene (50 ml) and methanol (50 ml). The polymer solution was passed through a short pad of Celite, and the polymer was eluted with further portions of toluene and methanol (200 ml). The polymer solution was evaporated to dryness in vacuo and then dissolved in a mixture of toluene (50 ml) and methanol (50 ml). The polymer solution was filtered through filter paper and precipitated from diethyl ether (600 ml, cooled) and washed with diethyl ether (3×50 ml). The resulting polymer was dried in a vacuum oven for 3 days to yield 1.36 g of a dark yellow solid.

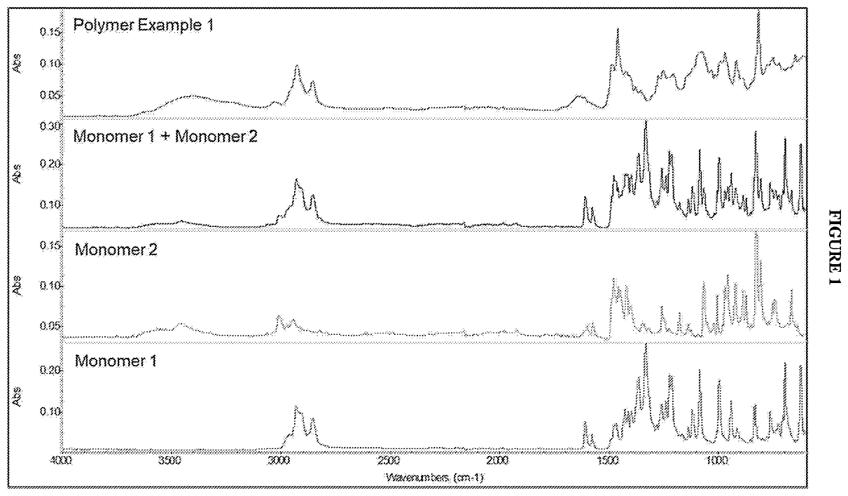

With reference to FIG. 1, significant differences are observed between the infrared spectra of the monomers 1 and 2 and the product obtained by reaction of these monomers, indicating polymerisation of these monomers.

Polymer 1 has a solubility of at least 0.5 mg/ml in methanol.

### POLYMER EXAMPLE 2

Polymer Example 2 was prepared according to the following reaction scheme:

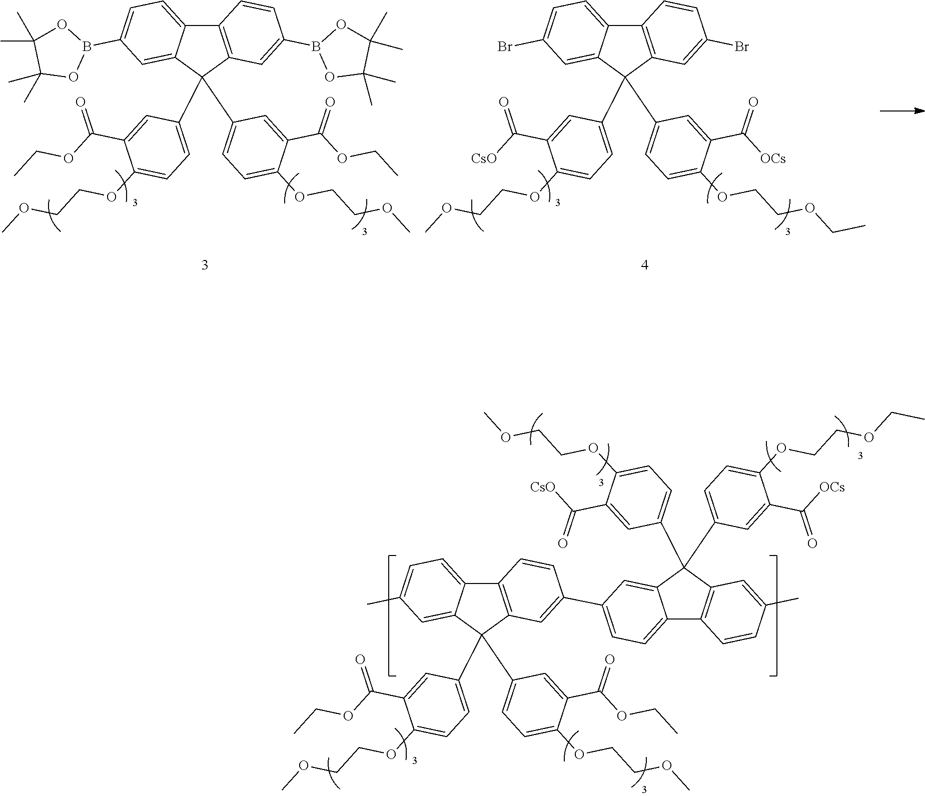

A reaction vessel was charged with monomer 3 (0.64 g, 0.619 mmol) and charged monomer 4 (0.73 g, 0.63 mmol) and the vessel was purged with nitrogen for 1 h. Toluene (20 ml, degassed by sparging with nitrogen for 30 mins) and methanol (20 ml, degassed by sparging with nitrogen for 30 mins) was added to the reaction vessel. The mixture was stirred until a clear solution was obtained, and the resulting stirred mixture was degassed (30 min sparging with nitrogen). Pd(OAc)₂ (4.2 mg, 0.02 mmol) and P(o-MeOPh)₃ (0.03 g, 0.08 mmol) were added to the mixture which was stirred and heated (oil bath 90° C.). A degassed (sparged with nitrogen for 1 h) solution of sodium carbonate (0.31 g, 2.94 mmol) in water (3.1 ml) was added dropwise to the stirred, heated reaction mixture. The reaction was stirred and heated. for 24 h, then 2,6-dimethylphenyl boronic acid (0.04 g, 0.25 mmol), in a mixture of toluene (2 ml) and methanol (2 ml), and Pd(OAc)₂ (4.2 mg, 0.02 mmol) and P(o-MeOPh)₃ (0.03 g, 0.08 mmol) were added. The resulting solution was stirred and heated for 14 hours, then cooled to room temperature. The aqueous phase was not separable, so the polymer was dried in vacuo to yield a dark solid, which was dissolved in a mixture of toluene (25 ml) and methanol (25 ml). The polymer solution was passed through a short pad of Celite, and the polymer was eluted with further portions of toluene and methanol (200 ml). The polymer solution was evaporated to dryness in vacuo and then dissolved in a mixture of toluene (20 ml) and methanol (20 ml). The polymer solution was filtered through filter paper and precipitated from diethyl ether (250 ml, cooled) and washed with diethyl ether (3×50 ml). The resulting polymer was dried in a vacuum oven for 24 h to yield 0.97 g of a dark grey brown solid.

Polymer 2 has a solubility of at least 1 mg/ml in both methanol and water.

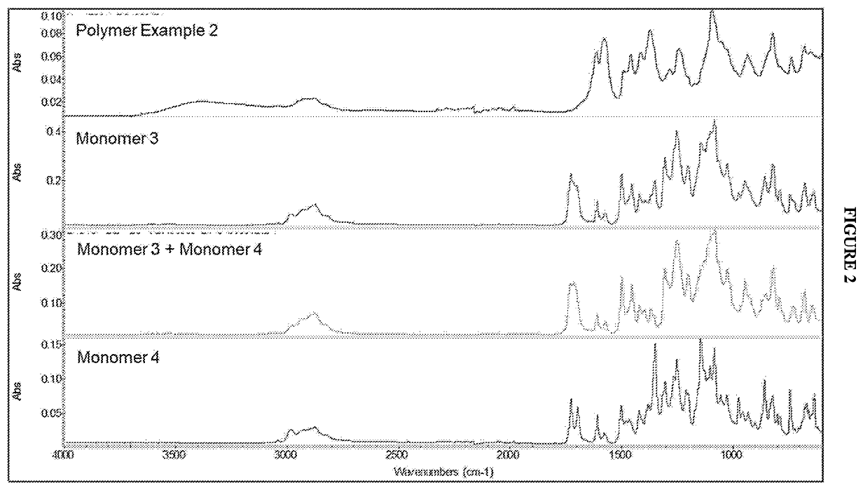

With reference to FIG. 2, significant differences are observed between the infrared spectra of the monomers 3 and 4 and the product obtained by reaction of these monomers, indicating polymerisation of these monomers.

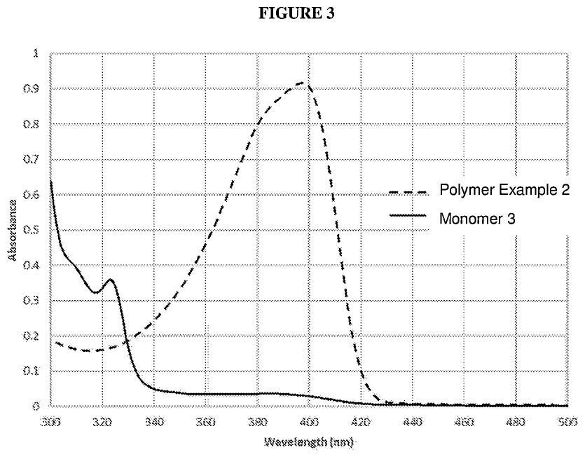

With reference to FIG. 3, the absorption spectra of Polymer Example 2 and Monomer 3 are very different, providing further evidence of polymerisation of the fluorene Monomers 3 and into polyfluorene Polymer Example 2.

1. A process of forming a conjugated polymer comprising polymerising a first monomer and a second monomer in the presence of a palladium catalyst and a base, in a solvent system comprising a first solvent and a second solvent; wherein:
the first and second monomers are dissolved in the solvent system;
the solvent system is a single phase;
the first monomer is a compound of Formula 1:
X¹-Ar¹-X¹ Formula 1
wherein Ar¹ comprises at least one aromatic or heteroaromatic group and is substituted with at least one ionic substituent comprising an anionic or cationic group and a counterion;
the second monomer is a compound of Formula 2:
X²-Ar²-X² Formula 2:
wherein Ar² comprises at least one aromatic or heteroaromatic group;
and each X¹ and X² is individually selected from a halogen, —OSO₂R^{a}, boronic acid, and a boronic ester, wherein R^{a} is an optionally substituted aryl or alkyl group; and at least one X¹ or X² is a halogen or —OSO₂R^{a}, the remaining X¹ and X² groups being a boronic acid, or a boronic ester.

2. The process according to claim 1 wherein the solvent system further comprises water.

3. The process according to claim 1, wherein the second solvent is a non-polar solvent.

4. The process according to claim 3, wherein the second solvent is selected from benzene having one or more alkyl substituents or a mixture thereof.

5. The process according to claim 1, wherein the second solvent is immiscible with water.

6. The process according to claim 1, wherein the first solvent is a polar solvent.

7. The process according to claim 5 wherein the first solvent is a protic solvent.

8. The process according to claim 5, wherein the first solvent is selected from C₁₋₁₀ alcohols or diols, tetrahydrofuran, acetic acid, acetone, dimethyl sulfoxide, N,N-dimethylformamide, acetonitrile or a mixture thereof.

9. The process according to claim 8 wherein the first solvent is selected from methanol, ethanol, propanol and butanol.

10. The process according to claim 1, wherein the first solvent is miscible with water.

11. The process according to claim 1 wherein the first solvent is miscible with the second solvent.

12. The process according to claim 1 wherein at least one of Ar¹ and Ar² is an arylene group.

13. The process according to claim 12 wherein the arylene group is selected from: 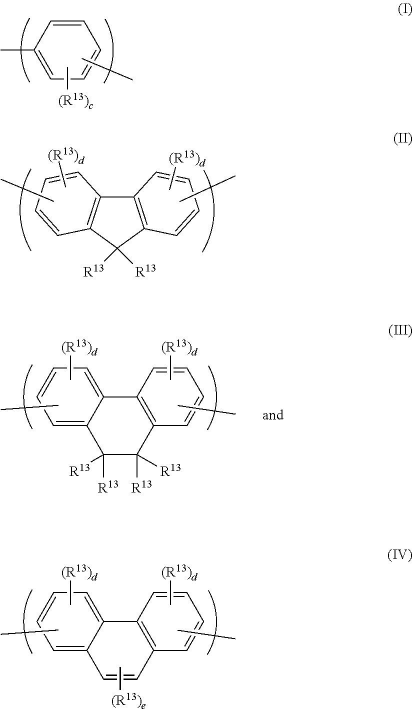
wherein each R¹³ is independently a substituent; c is 0, 1, 2, 3 or 4, each d is independently 0, 1, 2 or 3; and e is 0, 1 or 2; provided that at least one R¹³ is an ionic substituent.

14. The process according to claim 1 wherein Ar¹ is an arylene group according to claim 13.

15. The process according to claim 1 wherein Ar² is an arylene group according to claim 13.

16. The process according to claim 1 wherein Ar² comprises a heteroarylene or a (hetero)arylamine group.

17. The process according to claim 1 wherein each Ar² is unsubstituted or substituted only with one or more non-ionic substituent.

18. The process according to claim 1, wherein Ar¹ is substituted with one or more ionic substituents of formula -(Sp)m-(R^{x})n wherein Sp is a spacer group; m is 0 or 1; R^{x} in each occurrence is an ionic group; n is 1 if m is 0; and n is at least 1, optionally 1, 2, 3 or 4, if m is 1.

19. The process according to claim 1, wherein each ionic group is individually selected from: 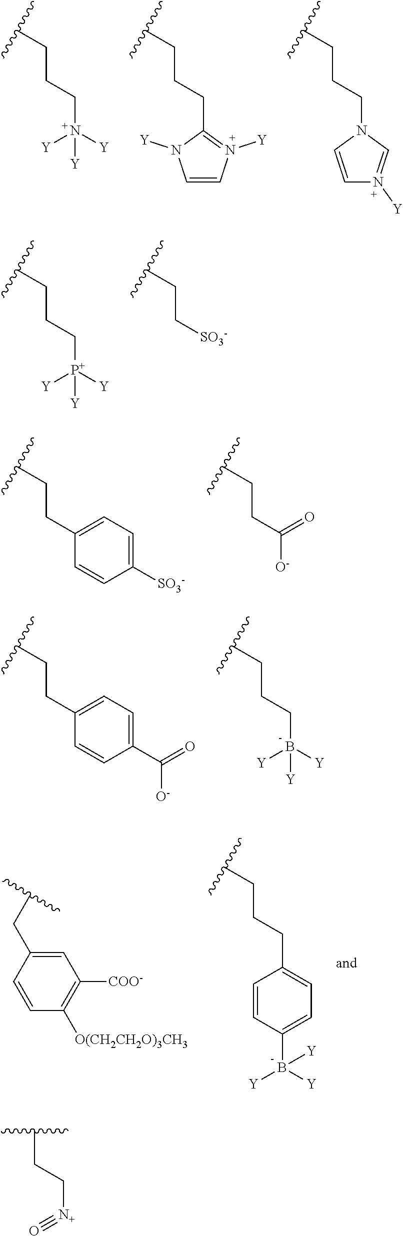
wherein each Y is individually selected from H, C₁-C₂₀ hydrocarbyl groups and C₁₋₃₀ alkyl in which one or more non-adjacent C atoms other than C atoms at the ends of the alkyl chain are replaced with O.

20. A process of forming a conjugated polymer comprising polymerising a first monomer and a second monomer in the presence of a palladium catalyst and a base, in a solvent system comprising a first solvent and a second solvent; wherein:
the first and second monomers are dissolved in the solvent system;
the solvent system is a single phase;
the first solvent is selected from C₁₋₁₀ alcohols or diols, tetrahydrofuran, acetic acid, acetone, dimethyl sulfoxide, N,N-dimethylformamide, acetonitrile or a mixture thereof;
the first monomer is a compound of Formula 1:
X¹-Ar¹-X¹ Formula 1
wherein Ar¹ comprises at least one aromatic or heteroaromatic group;
the second monomer is a compound of Formula 2:
X²-Ar²-X² Formula 2:
wherein Ar² comprises at least one aromatic or heteroaromatic group;
and each X¹ and X² is individually selected from a halogen, —OSO₂R^{a}, boronic acid, and a boronic ester, wherein R^{a} is an optionally substituted aryl or alkyl group; and at least one X¹ or X² is a halogen or —OSO₂R^{a}, the remaining X¹ and X² groups being a boronic acid, or a boronic ester;
the first monomer has a greater solubility in water at 25° C. than the second monomer; and
the second monomer has a greater solubility in toluene at 25° C. than the first monomer.
